(19) United States
(12) Patent Application Publication
(10) Pub. No.: US 2008/0012062 A1
(43) Pub. Date: Jan. 17, 2008

(54) EEPROM DEVICE AND METHOD OF FABRICATING THE SAME

(75) Inventors: Hyun-Khe YOO, Suwon-si (KR); Jeong-Uk HAN, Suwon-si (KR); Hee-Seog JEON, Suwon-si (KR); Sung-Gon CHOI, Osan-si (KR); Bo-young SEO, Suwon-si (KR); Chang-Min JEON, Giheung-gu (KR); Ji-Do RYU, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/775,871

(22) Filed: Jul. 11, 2007

(30) Foreign Application Priority Data
Jul. 14, 2006 (KR) 2006-66526

(51) Int. Cl. H01L 29/788; H01L 21/336

(52) U.S. Cl. 257/316; 438/257; 257/E29.3; 257/E21.409

(57) ABSTRACT

An electrically erasable programmable read-only memory (EEPROM) device includes an EEPROM cell located on a semiconductor substrate, the EEPROM cell including a memory transistor and a selection transistor. A source region and a drain region are located on the semiconductor substrate adjacent to opposite sides of the EEPROM cell, respectively, and a floating region is positioned between the memory transistor and the selection transistor. The source region includes a first doped region, a second doped region and a third doped region, where the first doped region surrounds a bottom surface and sidewalls of the second doped region, and the second doped surrounds a bottom surface and sidewalls of the third doped region. Also, a second impurity concentration of the second doped region is higher than that of the first doped region and lower than that of the third doped region.

### CROSS-REFERENCE TO RELATED APPLICATIONS

A claim of priority is made to Korean Patent Application 10-2006-0066526, filed on Jul. 14, 2006, the subject matter which is hereby incorporated by reference.

### BACKGROUND OF THE INVENTION

1. Field of the Invention

The present invention relates to semiconductor devices and methods of fabricating the same. More particularly, the present invention is directed to an electrically erasable programmable read-only memory (EEPROM) device and a method of fabricating the same.

2. Description of the Related Art

An EEPROM device is a non-volatile memory device, which retains its stored data even when its power supply is interrupted. A two-transistor EEPROM device includes an EEPROM cell having a memory transistor and a selection transistor.

As with other memory devices, smaller EEPROM cells make threshold voltage distribution of a programmed or erased cell wider, causing difficulty in securing sufficient current. Accordingly, efforts have been made to overcome the problems caused by smaller cells (e.g., cell shrinkage).

FIG. 1 is a cross-sectional view of a conventional two-transistor Fowler-Nordheim (FN) tunneling EEPROM cell. The EEPROM cell includes a memory transistor and a selection transistor, and is symmetrically disposed in a mirror-image on a semiconductor substrate. In the EEPROM cell, adjacent memory transistors share a source region 30s connected to a common source region, and adjacent selection transistors share a drain region 30d.

A gate stack 14 of the memory transistor (memory gate stack 14) and a gate 16 of the selection transistor (selection gate 16) are positioned on a semiconductor substrate 10. Spacer patterns 17 are formed on sidewalls of each memory gate stack 14 and selection gate 16. Each of the source region 30s and the drain region 30d includes a first doped region 24 and a second doped region 26. A floating region 22 is formed in the semiconductor substrate 10 between the first doped region 24 and the second doped region 26. The floating region 22 extends to a semiconductor substrate below the memory gate stack 14. The memory gate stack 14 includes an intergate dielectric, a floating gate 18 and a control gate electrode 20.

In the EEPROM cell, program and erase operations are performed by FN tunneling through a thin portion of a gate insulator formed below the floating gate 18, the thin portion being referred to as tunnel insulator 12t.

When a logic low signal is transmitted to the floating region 22 from the drain region 30d through the channel of the selection transistor and a high positive program voltage is applied to the memory gate stack 14 during a program mode, electrons tunneling through the tunnel insulator 12t are stored in the floating gate 18. In contrast, when a high negative erase voltage is applied to the memory gate stack 14 during the program mode, the electrons stored in the floating gate are ejected to the floating region 22 through the tunnel insulator 12t.

The conventional EEPROM has exhibits low integration density because the floating region 22 overlaps the tunnel insulator 12t. In order to increase the integration density, linewidths of the memory gate stack 14 and the selection gate 16 are reduced, and areas of the source region 30s and the drain region 30d are reduced.

The first doped region 24 is conventionally formed by doping impurities at a dose of 1×10¹²˜1×10¹³ ions/cm², and the second doped region 26 is conventionally formed by doping impurities at a dose of 1×10¹⁵˜1×10¹⁶ ions/cm².

A source region of a double diffused drain (DDD) structure including the first doped region 24 and the second doped region 26 is configured in which a lightly doped region surrounds a heavily doped region. The DDD structure is advantageous to a high junction breakdown voltage and prevention of punch-through.

An advantage of the first doped region having a low concentration is that the concentration of the first doped region affects punch-through, while an advantage of the second doped region having a high concentration is that the concentration of the second doped region affects resistance. However, when there is a short distance between junctions of the first and second doped regions, or when there is a larger difference between the doped concentrations of the first and second doped regions, a breakdown voltage may drop. Accordingly, there is a limitation with respect to the concentration of a doped region in a DDD structure.

When silicide is formed on a source region and a drain region to adopt a low-resistance silicide structure, the silicide extends to the first doped region having a low concentration through the second doped region having a high concentration to increase leakage current.

In an EEPROM memory device with a NOR cell array structure, the source region 30s is connected in parallel to a wordline to constitute a common source region. Attempts to reduce an area of the source region 30s for higher integration increase resistance because a concentration of a lightly doped region in a DDD structure is low. Further, a width of the second doped region (having a high concentration) aligned between the spacer patterns 17 is reduced, further increasing the resistance.

Accordingly, the resistance increase becomes greater under a structure, such as a common source structure, where hopping distances of carriers are relatively long. When the resistance of a common source line is high, the intensity of a transmitted signal is lowered according to the hopping distances of carriers to sense that a threshold voltage distribution of a memory cell array is high.

### SUMMARY OF THE INVENTION

An aspect of the present invention provides an electrically erasable programmable read-only memory (EEPROM) device, including a semiconductor substrate and an EEPROM cell, having a memory transistor and a selection transistor, located on the semiconductor substrate. The EEPROM device also includes a source region and a drain region located on the semiconductor substrate adjacent to opposite sides of the EEPROM cell, respectively, as well as a floating region positioned between the memory transistor and the selection transistor. The source region has a first doped region, a second doped region and a third doped region, where the first doped region surrounds a bottom surface and sidewalls of the second doped region, and the second doped region surrounds a bottom surface and sidewalls of the third doped region. Also, a second impurity concentration of the second doped region may be higher than a first impurity concentration of the first doped region and lower than a third impurity concentration of the third doped region. The EEPROM device may further include a self-aligned silicide layer on the third doped region.

Impurity ions in the first doped region and third doped region may include phosphorus (P) and arsenic (As), and impurity ions in the second doped region may include As. Also, each of the floating region and the drain region may have the same impurity concentration and depth as either the first doped region or the second doped region.

Another embodiment of the present invention provides an EEPROM device, which includes an active region defined on a semiconductor substrate; a first drain region and a second drain region separated from each other in the active region; a first sensing line and a second sensing line positioned between the first drain region and the second drain region, and crossing over the active region adjacent to each of the first drain region and the second drain region; and a first wordline and a second wordline positioned between the first sensing line and the second sensing line. Spacer patterns are positioned on sidewalls of the first and second sensing lines and the first and second wordlines. A first floating region is positioned on the active region between the first wordline and the first sensing line, and a second floating region positioned on the active region between the second wordline and the second sensing line. Also, a common source region is positioned on the active region between the first wordline and the second wordline, and includes a first doped region, a second doped region and a third doped region. The first doped region surrounds a bottom surface and sidewalls of the second doped region, and the second doped region surrounds a bottom surface and sidewalls of the third doped region.

A portion of the active region between the first and second wordlines may be exposed between adjacent spacer patterns, and portions of the active region between the first wordline and the first sensing line and between the second wordline and the second sensing line may be covered by adjacent spacer patterns. The EEPROM device may further include a silicide layer positioned on the exposed portion of the active region between the first and second wordlines and aligned with an outer sidewall of each of the adjacent spacer patterns. Each of the first wordline and the second wordline may be partially superposed on the first doped region and each of the adjacent spacer patterns may be superposed on the second doped region. The third doped region may be located within the exposed portion of the active region between the first and second wordlines.

Each of the first and second floating regions and the first and second drain regions may have the same impurity concentration and depth as the first doped region or the second doped region. Further, the impurity ions implanted into the first doped region and the third doped region may include phosphorus (P) and arsenic (As), and impurity ions implanted into the second doped region may include As. The impurity ions implanted into each of the first and second floating regions and the first and second drain regions may include P and arsenic As, or just As.

Yet another aspect of the present invention provides a method of fabricating an EEPROM device, including forming a memory gate stack and a selection gate on a semiconductor substrate. The method further includes implanting impurities into the semiconductor substrate to form a floating region between opposing sidewalls of the memory gate stack and the selection gate, to form a first doped region adjacent to an opposite sidewall of the selection gate, to form a second doped region having a bottom surface and sidewalls surrounded by the first doped region, and to form a drain region adjacent to an opposite sidewall of the memory stack gate. Spacer patterns are formed on the sidewalls of the selection gate and the memory gate stack. Impurities are implanted into the semiconductor substrate to form a third doped region adjacent to the spacer pattern formed on the opposite sidewall of the selection gate, the third doped region having a bottom surface and sidewalls surrounded by the second doped region. The floating region and the drain region may be formed simultaneously with either the first doped region or the second doped region. The method may further include applying a self-aligned silicide layer to the semiconductor substrate on the third doped region.

### BRIEF DESCRIPTION OF THE DRAWINGS

The embodiments of the present invention will be described with reference to the attached drawings, in which:

FIG. 1 is a cross-sectional view of a conventional EEPROM device;

FIGS. 2 and 3 illustrate an EEPROM device, according to a first exemplary embodiment of the present invention;

FIGS. 4 through 8 are cross-sectional views illustrating a method of fabricating an EEPROM device, according to the first embodiment of the present invention;

FIGS. 9 and 10 illustrate an EEPROM device according to a second exemplary embodiment of the present invention; and

FIGS. 11 through 14 are cross-sectional views illustrating a method of fabricating an EEPROM device according to the second embodiment of the present invention.

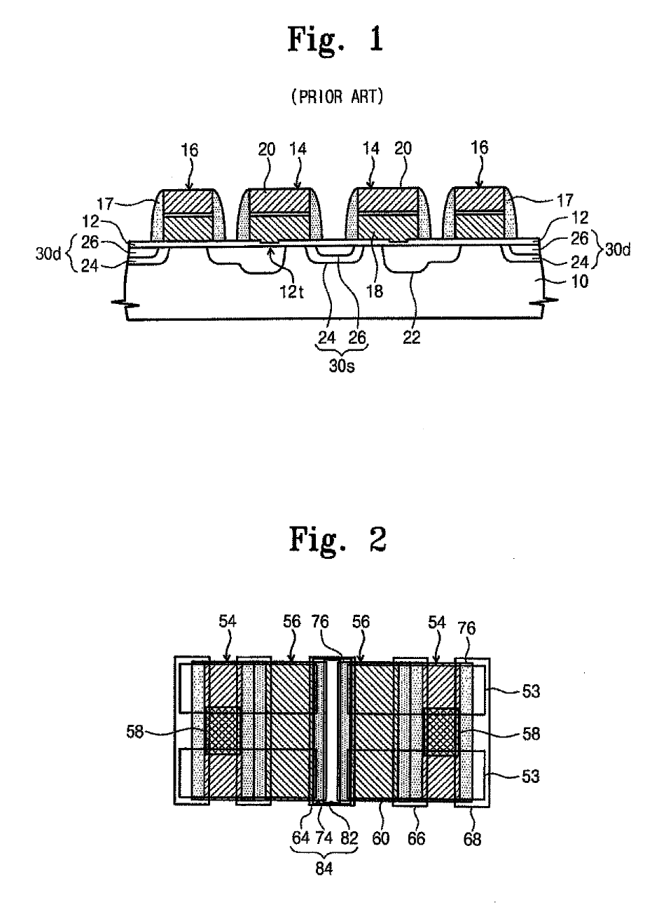

### DETAILED DESCRIPTION OF EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention.

In the drawings, the thicknesses of layers and regions are exaggerated for clarity. It will also be understood that when a layer is referred to as being “on” another layer or substrate, it can be directly on the other layer or substrate, or intervening layers may also be present. Throughout the drawings and written description, like reference numerals will be used to refer to like or similar elements.

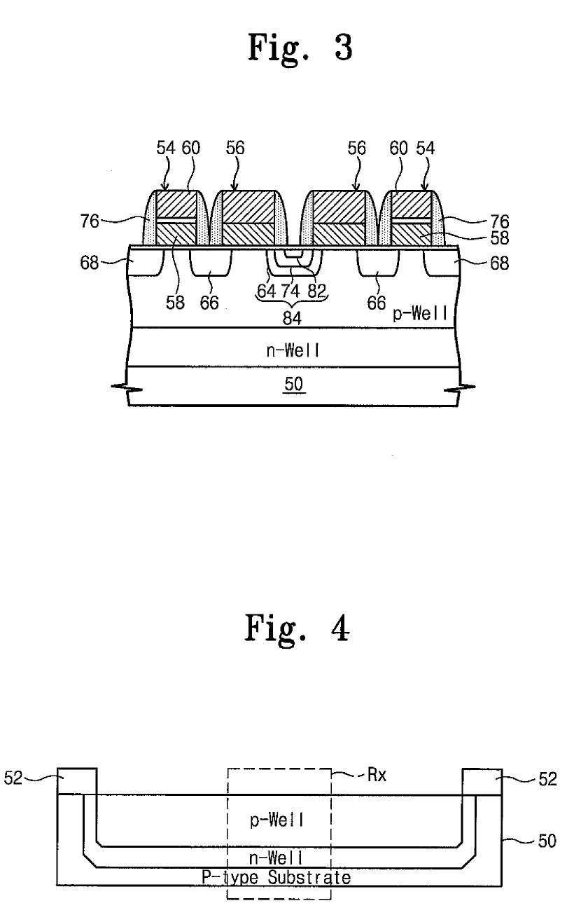

FIGS. 2 and 3 illustrate an EEPROM device according to a first exemplary embodiment of the present invention. FIG. 2 is a top plan view illustrating the EEPROM device according to the first embodiment, and FIG. 3 is a cross-sectional view of the EEPROM device of FIG. 2.

Referring to FIGS. 2 and 3, a device isolation layer 53 is located on a semiconductor substrate 50 to define an active region. The semiconductor substrate 50 may have P-type conductivity. Impurities are implanted into the semiconductor substrate 50 to form an N-well and a P-well. A lower portion and a sidewall of the P-well may be successively surrounded by the N-well to isolate the P-well from the semiconductor substrate 50.

A memory gate stack 54 of a memory transistor and a selection gate 56 of a selection transistor are located on the semiconductor substrate 50, the selection gate 56 being spaced apart or separated from the memory gate stack 54. The memory gate stack 54 includes a floating gate 58 on the active region and a control gate electrode 60 overlapping the floating gate 58 to cross over the active region and the device isolation layer 53. An intergate dielectric may be located between the floating gate 58 and the control gate electrode 60, and a tunnel insulation layer may be located between the floating gate 58 and the active region.

The selection gate 56 may include a lower conductive layer and an upper conductive layer, or a single conductive layer. The selection gate 56 crosses over the active region and the device isolation layer 53, running parallel to the control gate electrode 60.

The lower conductive layer and the floating gate 58 are formed by etching a first conductive layer, and the upper conductive layer and the control gate electrode 60 are formed by etching a second conductive layer. A dielectric film, which is identical to the intergate dielectric, may be interposed between the lower conductive layer and the upper conductive layer. The dielectric film is partially removed to electrically connect the lower and upper conductive layers to each other.

In the semiconductor substrate 50, a common source region 84 runs parallel to the control gate electrode 60. The selection gate (wordline) 56 and the memory gate stack (sensing line) 54 are positioned in the direction of the common source region 84. The selection gate 56 and the memory gate stack 54 are symmetrically repeated in a mirror-image relative to the common source region 84.

A spacer pattern 76 is each formed on each of the sidewalls of the memory gate stack 54 and the selection gate 56. The spacer patterns 76 between the memory gate stack 54 and the selection gate 56 may be connected to each other to cover the active region. However, the spacer patterns 76 adjacent to a drain region 68 and the source region 84 cover only a portion of the drain region 68 and the source region 84, respectively.

The source region 84 includes a first doped region 64, a second doped region 74, and a third doped region 82, which are sequentially positioned from the inside to the surface of the semiconductor substrate 50. The first doped region 64 successively surrounds a bottom surface and sidewalls of the second doped region 74, and the second doped region 74 successively surrounds a bottom surface and sidewalls of the third doped region 82. An impurity concentration of the second doped region 74 is higher than that of the second doped region 74 and lower than that of the third doped region 82.

In the first embodiment, impurity concentrations of a floating region 66 and the drain region 68 may each be equivalent to the impurity concentration of the first doped region 64. Further, depths of the floating region 66 and the drain region 68 may each be equivalent to a depth of the first doped region 64. For example, the first doped region 64, the floating region 66, and the drain region 68 may be formed simultaneously by means of ion implantation. Also, the first doped region 64, the floating region 66 and the drain region 68 have the same lateral diffusion distance from sidewalls of a memory gate stack 54 or sidewalls of a selection gate 56 to a portion below the memory gate stack 54 or the selection gate 56, respectively.

The wordline (selection gate 56) is partially superposed on the first doped region 64, and the spacer patterns 76 are superposed on the second doped region 64. The third doped region 82 is formed in an active region between the spacer patterns 76.

Although not shown in the figures, a silicide layer may further be included on the third doped region 82 to lower the resistance of the common source region 84. The silicide layer is self-aligned with the outer sidewall of the spacer patterns 76 of adjacent selection gates 56 to be positioned at the active region.

In the EEPROM device according to the disclosed embodiment, a channel of a selection transistor is defined by the active region between the source region 84 and the floating region 66. A channel of a memory transistor is defined by the active region between the floating region 66 and the drain region 68.

During a program mode, a negative voltage is applied to the wordline (selection gate 56) and a positive program voltage is applied to the sensing line (memory gate stack 54) of a selected EEPROM cell. When the negative voltage is applied to a drain region 68 of the selected EEPROM cell, the channel of the memory transistor becomes negative potential. Thus, electrons tunnel to the floating gate 58 through the tunnel insulation layer to be stored.

A program inhibit voltage is applied to a drain region 68 of an unselected EEPROM cell, so that an unselected memory transistor is not programmed. The program inhibit voltage may be a positive voltage or a ground voltage.

During an erase mode, a ground voltage or a positive voltage is applied to the wordline (selection gate 56), a negative voltage is applied to the sensing line (memory gate stack 54), a positive voltage is applied to the P-well, and the source region 84 and the drain region 68 float. Due to a potential difference between the sensing line and the P-well, the electrons stored in the floating gate 58 tunnel through the tunnel insulation layer.

In the present embodiment, impurities in the first doped region 64 may be phosphorus (P) and arsenic (As), impurities in the second doped region 74 may be As, and impurities in the third doped region 82 may be P and As.

FIGS. 4 through 8 are cross-sectional views illustrating a method of fabricating an EEPROM device according to the first embodiment of the present invention.

Referring to FIG. 4, a deep N-well is formed in a semiconductor substrate 50. Using an ion implantation mask, a P-well is formed within the N-well. The semiconductor substrate 50 may be a P-type substrate, for example.

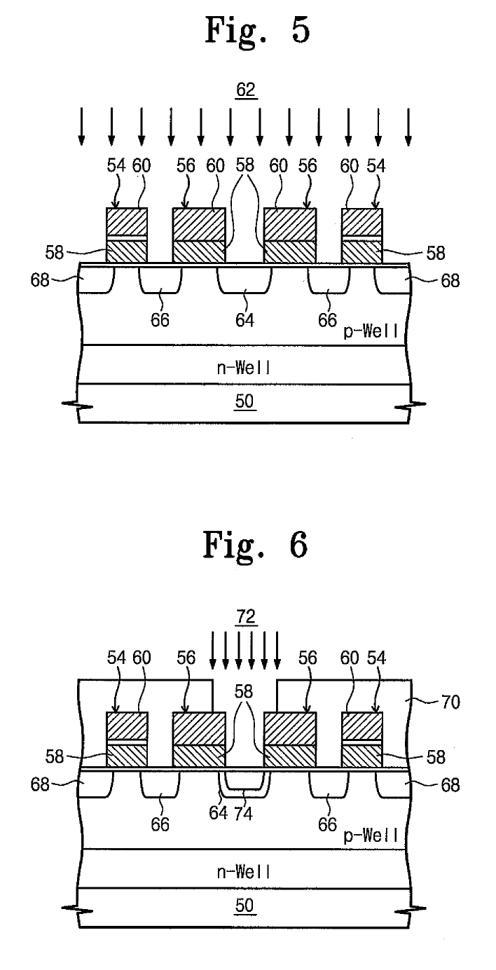

Referring to FIG. 5, a method of fabricating an EEPROM device will be described using a partial region Rx of a semiconductor substrate 50. As illustrated in FIGS. 2 and 3, a device isolation layer 53 is formed to define an active region on a semiconductor substrate 50. A selection gate 56 and a memory gate stack 54 are formed to cross over the active region and the device isolation layer 53.

During a first ion implanting process 62, using the selection gate 56 and the memory gate stack 54 as ion implantation masks, impurities are implanted into the active region to form a first doped region 64, a floating region 66 and a drain region 68. In the depicted embodiment, the impurities implanted in the active region are N-type impurities such as, for example, phosphorus (P) and arsenic (As). The first ion implanting process may be performed with energy ranging from 25 to 60 keV at a dose of 1.0×10¹²˜1.0×10¹⁴ ions/cm².

The first ion implanting process 62 is restrictively performed only at a cell array region and impurities may not be implanted into the active region of a peripheral circuit region.

Referring to FIG. 6, a first ion implanting mask 70 is formed on the surface of the semiconductor substrate 50. The first ion implanting mask 70 has an opening that exposes the first doped region 64. The opening extends in parallel with the selection gate 56. A portion of the selection gate 56 may also be exposed by the opening.

A second ion implanting process 72 is performed using the first ion implantation mask 70. Impurities are implanted into the substrate, where the first doped region 64 is formed, to form a second doped region 74. An impurity projection range of the second ion implanting process 72 is smaller than that of the first ion implanting process 62. Therefore, the second doped region 74 is formed within the first doped region 64, i.e., the first doped region 64 surrounds the bottom surface and sidewalls of the second doped region 74.

During the second ion implanting process 72, N-type impurities may be implanted. For example, arsenic ions may be implanted into the active region. The second ion implanting process 72 may be performed with energy ranging from 20 to 55 keV at a dose of 1.0×10¹⁴˜1.0×10¹⁵ ions/cm². Thus, the second doped region 74 is formed to have a smaller thickness than the first doped region 64 and to have a higher impurity concentration than the first doped region 64.

During the second ion implanting process 72, P-type impurities may be implanted before the implantation of the N-type impurities. For example, boron (B) ions may be implanted with energy ranging from 20 to 60 keV at a dose of 1.0×10¹³˜5.0×10¹³ ions/cm². Due to the P-type impurities, a diffusion distance of the N-type impurities is limited and a breakdown voltage rises.

The first ion implantation mask 70 may also have an opening exposing a portion of a peripheral circuit, and impurities may be implanted into a portion of an active region of the peripheral circuit to form a doped region.

The first doped region 64 is diffused to the substrate below the memory gate stack 54 and the selection gate 56. The second doped region 74 may be aligned with the sidewalls of the memory gate stack 54 and the selection gate 56. Alternatively, the second doped region 74 may be diffused to the substrate below each of the memory gate stack 54 and the selection gate 56, although a diffusion distance of the second doped region 74, i.e., an overlap width of the second doped region 74 with each of the memory gate stack 54 and the selection gate 56, is less than the diffusion distance of the first doped region 64, i.e., an overlap width of the first doped region 64 with each of the memory gate stack 54 and the selection gate 56.

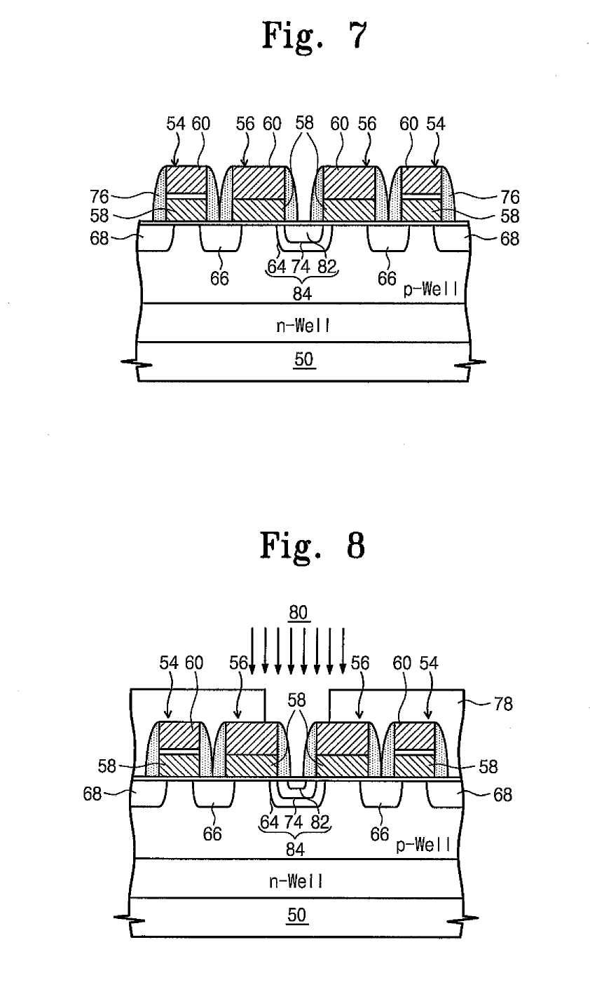

Referring to FIG. 7, the first ion implantation mask 70 is removed. Spacer patterns 76 are formed on sidewalls of each of the memory gate stack 54 and the selection gate 56. When a space between the memory gate stack 54 and the selection gate 56 is reduced, the spacer pattern 76 therebetween may be connected to each other.

Referring to FIG. 8, a second ion implantation mask 78 is formed on the surface of the substrate. The second ion implantation mask 78 has an opening, which extends in parallel with the selection gate 56 and may be formed to expose a portion of the selection gate 56.

A third ion implanting process 80 is performed using the second ion implantation mask 78. Impurities are implanted into the substrate, where the second doped region 74 is formed, to form a third doped region 82. An impurity projection range of the third ion implanting process 80 is less than that of the second ion implanting process 72. Therefore, the third doped region 82 is formed within the second doped region 74, i.e., the second doped region 74 surrounds the bottom surface and sidewalls of the third doped region 82. The third doped region 82 is aligned with the spacer patterns 76 and formed at the exposed active region between the spacer patterns 76.

During the third ion implanting process 80, N-type impurities may be implanted. For example, phosphorus and arsenic ions are implanted into the active region. The third ion implanting process 80 may be performed with energy ranging from 3 to 10 keV at a dose of 1.0×10¹⁵˜7.0×10¹⁵ ions/cm². Thus, the third doped region 82 is formed to have a smaller thickness than the second doped region 74 and to have a higher impurity concentration than the second doped region 74.

The second ion implantation mask 78 may also have an opening exposing a portion of a peripheral circuit, and impurities may be implanted into a portion of an active region of the peripheral circuit to form a doped region. Thus, a source region and/or a drain region including the second and third doped regions 74 and 82 may be formed at the peripheral circuit region.

As a result, a source region 84 is formed, including the first region 64, the second region 74 and the third region 82. The source region 84 extends in parallel with the selection gate 56, forming a common source region.

The source region 84 has a graded structure where its concentration is gradually reduced from a boundary of the P-well. The graded structure of the source region 84 may be formed, for example, by means of a special annealing process to diffuse impurities or by means of an annealing process performed during fabrication of the EEPROM device. Due to the graded structure, generation of punch-through is suppressed and a high breakdown voltage is generated.

Following the removal of the second ion implantation mask 78, a self-aligned silicide layer, i.e., salicide layer (not shown), may be formed on the source region 84 and the drain region 68 by means of a self-aligned silicidation process. The salicide layer may be formed on the third doped region 82 of the source region 84 to be self-aligned with the outer sidewall of the spacer patterns 76. The salicide layer may not be formed at the active region between the memory gate stack 54 and the selection gate 56 when, for example, a space between the memory gate stack 54 and the selection gate 56 is so narrow that the spacer patterns 76 cover the floating region 66.

In the present embodiment, even when the salicide layer extends to the substrate, increase of leakage current is suppressed at the source region 84, which includes the first doped region 64, the second doped region 74 and the third doped region 82.

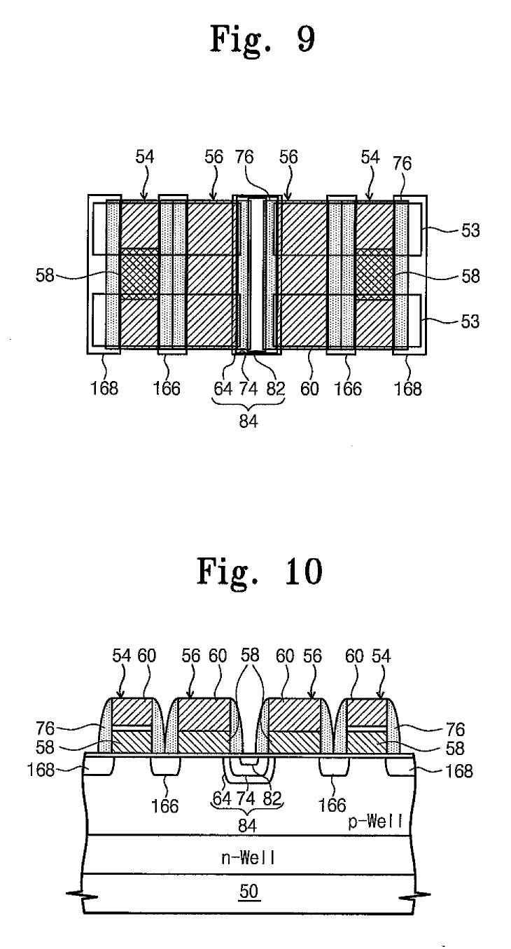

FIGS. 9 and 10 illustrate an EEPROM device according to a second exemplary embodiment of the present invention. FIG. 9 is a top plan view illustrating the EEPROM device according to the second embodiment, and FIG. 10 is a cross-sectional view of the EEPROM device of FIG. 9.

Referring to FIGS. 9 and 10, similar to the first embodiment, a memory gate stack 54 is positioned on a semiconductor substrate 50. A selection gate 56 is positioned separate from the memory gate stack 54. The memory gate stack 54 includes a floating gate 58 located on an active region and a control gate electrode 60 overlapping the floating gate 58 to cross over the active region and a device isolation layer 53.

The selection gate 56 may include a lower conductive layer and an upper conductive layer, or a single conductive layer. The selection gate 56 crosses over the active region and the device isolation layer 53, running parallel to the control gate electrode 60.

A common source region 84 is formed within the semiconductor substrate, running parallel to the control gate electrode 60. The selection gate (wordline) 56 and the memory gate stack (sensing line) 54 are positioned in one direction of the common source region 84. The memory gate stack 54 and the selection gate 56 are symmetrically repeated in a mirror-image relative to the common source region 84.

A spacer pattern 76 is formed on each sidewall of the memory gate stack 54 and the selection gate 56. Opposing spacer patterns 76 located between the memory gate stack 54 and the selection gate 56 may be connected to each other to cover the active region. However, the spacer patterns 76 adjacent to a drain region 168 and the source region 84 are each formed only on a portion of the drain region 168 or the source region 84, respectively.

The source region 84 comprises a first doped region 64, a second doped region 74 and a third doped region 82, which are sequentially positioned from the inside to the surface of the semiconductor substrate 50. The first doped region 64 successively surrounds a bottom surface and sidewalls of the second doped region 74, and the second doped region 74 successively surrounds a bottom surface and sidewalls of the third doped region 82.

An impurity concentration of the second doped region 74 is higher than that of the second doped region 74, and lower than that of the third doped region 82.

In the second embodiment, impurity concentrations of a floating region 166 and the drain region 168 are each equivalent to the impurity concentration of the first doped region 64. Further, depths of the floating region 166 and the drain region 168 are each equivalent to a depth of the second doped region 74. For example, the first doped region 64, the floating region 166 and the drain region 168 may be formed simultaneously by means of ion implantation. The second doped region 74, the floating region 166 and the drain region 168 may have the same lateral diffusion distance from a sidewall of a memory gate stack 54 or a selection gate 56 to a portion below the memory gate stack 54 or the selection gate 56, respectively.

The wordline (selection gate 56) is at least partially superposed on the first doped region 64, and the spacer pattern 76 is superposed on the second doped region 74. The third doped region 82 is formed in an active region between the spacer patterns 76.

Although not shown in the figures, a silicide layer may further be disposed on the third doped region 82 to lower the resistance of the common source line 84. The silicide layer is self-aligned with the outer sidewall of the spacer patterns 76 to be disposed on the active region.

In an EEPROM cell according to the present embodiment, a channel of a selection transistor (e.g., including the selection gate 56) is defined by the active region between the source region 84 and the floating region 166. Also, a channel of a memory transistor (e.g., including the memory stack gate 54) is defined by the active region between the floating region 166 and the drain region 168.

In the present embodiment, impurities in the first doped region 64 may be phosphorus (P) and arsenic (As), impurities in the second doped region 74 may be As, and impurities in the third doped region 82 may be P and As, for example.

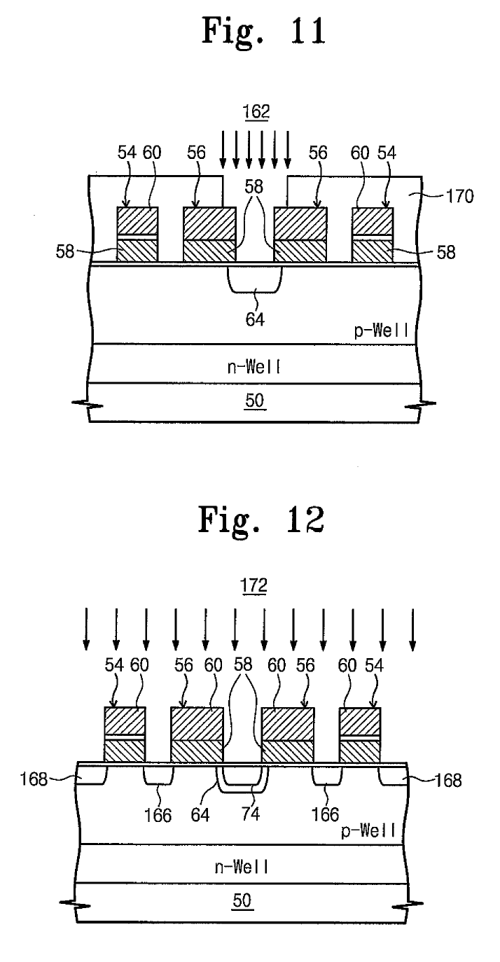

FIGS. 11 through 14 are cross-sectional views illustrating a method of fabricating an EEPROM device according to the second embodiment of the present invention.

Referring to FIG. 11, an active region is defined on a semiconductor substrate 50, and a selection gate 56 and a memory gate stack 54 are formed to cross over the active region and a device isolation layer 53, as illustrated in FIG. 9.

A first ion implantation mask 170 is formed on the substrate. The first ion implantation mask 170 has an opening that exposes the active region between the selection gates 56. A first ion implanting process 162 is performed using the first ion implantation mask 170. During the first ion implanting process 162, impurities are implanted into the active region to form a first doped region 64.

During the first ion implanting process 162, N-type impurities such as, for example, phosphorus (P) and arsenic (As) ions, are implanted into the active region. The implantation may be implanted with energy ranging from 25 to 60 keV at a dose of 1.0×10¹²˜1.0×10¹⁴ ions/cm².

Referring to FIG. 12, the first ion implantation mask 170 is removed.

A second ion implanting process 172 is performed using the memory gate stack 54 and the selection gate 56 as an ion implantation mask. Impurities are implanted into the substrate, where the first doped region 64 is formed, to form a second doped region 74. An impurity projection range of the second ion implanting process 172 is smaller than that of the first ion implanting process 162. Therefore, the second doped region 74 is formed within the first doped region 64, i.e., the first doped region 64 surrounds a bottom surface and sidewalls of the second doped region 74.

Simultaneously to the formation of the second doped region 74, a floating region 166 is formed between the memory gate stack 54 and the selection gate 56, and a drain region 168 is formed adjacent to each of the memory gate stacks 54. At this point, impurities may also be implanted into a portion of the active region of a peripheral circuit to form a doped region.

During the second ion implanting process 172, N-type impurities may be implanted. For example, arsenic ions may be implanted into the active region. The second ion implanting process 172 may be performed with energy ranging from 20 to 55 keV at a dose of 1.0×10¹⁴˜1.0×10¹⁵ ions/cm². Thus, the second doped region 74 is formed to have a smaller thickness than the first doped region 64 and have a higher impurity concentration than the first doped region 64.

During the second ion implanting process 72, P-type impurities may be implanted before the implantation of the N-type impurities. For example, boron (B) ions may be implanted with energy ranging from 20 to 60 keV at a dose of 1.0×10¹³˜5.0×10¹³ ions/cm². Due to the P-type impurities, a diffusion distance of the N-type impurities is limited and a breakdown voltage rises.

The first doped region 64 is diffused to the substrate 50 below the memory gate stack 54 and the selection gate 56. The second doped region 74 may be aligned with the sidewalls of the selection gates 56 or may be diffused to the substrate below the selection gates 56. However, when the second doped region 74 is diffused below the selection gates 56, the diffusion distance of the second doped region 74, i.e., an overlap width of the second doped region 74 with the selection gates 56, is less than an overlap width of the first doped region 64 therewith.

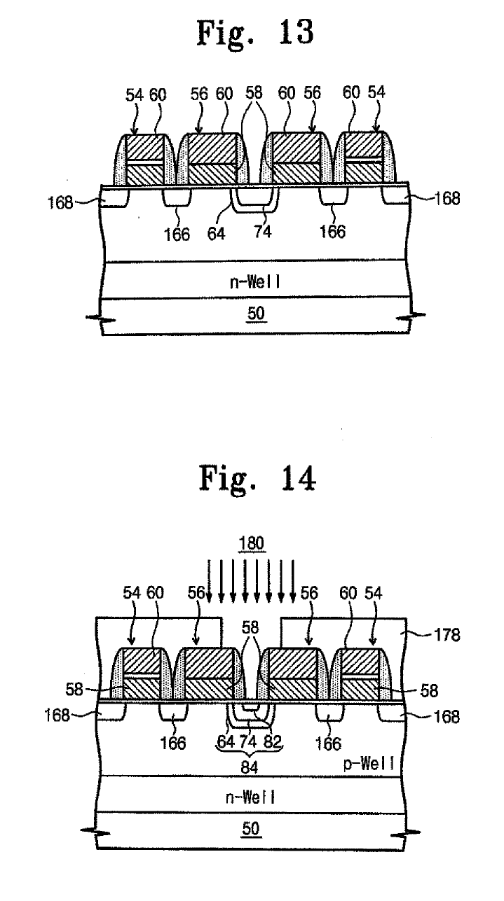

Referring to FIG. 13, a spacer pattern 76 is formed on each of the sidewalls of the memory gate stacks 54 and the selection gates 56. When a space between the memory gate stack 54 and the selection gate 56 is narrow, the opposing spacer patterns 76 formed between the memory gate stack 54 and the selection gate 56 may be connected to each other.

Referring to FIG. 14, a second ion implantation mask 178 is formed on the surface of the substrate. The second ion implantation mask 178 has a second opening that exposes the second doped region 74. The second opening extends in parallel with the selection gates 56, and a portion of each selection gate 56 may be exposed by the second opening.

A third ion implanting process 180 is performed using the second ion implantation mask 178. Impurities are implanted into the substrate, where the second doped region 74 is formed, to form a third doped region 82. An impurity projection range of the third ion implanting process 180 is less than the impurity projection range of the second ion implanting process 172. Therefore, the third doped region 82 is formed within the second doped region 74, i.e., the second doped region 74 surrounds a bottom surface and sidewalls of the third doped region 82. The third doped region 82 is aligned with the spacer patterns 76 and formed at the exposed active region between the spacer patterns 76.

During the third ion implanting process 180, N-type impurities may be implanted. For example, phosphorus and arsenic ions may be implanted into the active region. The third ion implanting process 180 may be performed with energy ranging from 3 to 10 keV at a dose of 1.0×10¹⁵˜7.0×10¹⁵ ions/cm². Thus, the third doped region 82 is formed to have a smaller thickness than the second doped region 74, and to have a higher impurity concentration than the second doped region 74.

The second ion implantation mask 178 may also have an opening that exposes a portion of a peripheral circuit, and impurities may be implanted into a portion of an active region of the peripheral circuit to form a doped region. Thus, a source region and/or a drain region including the second and third doped regions 74 and 82 may be formed at the peripheral circuit region.

As a result, a source region 84 is formed, including the first dope region 64, the second doped region 74 and the third doped region 82. The source region 84 extends in parallel with the selection gate 56 to form a common source region.

The source region 84 has a graded structure, in which its concentration is gradually reduced from a boundary of a P-well. For example, a second impurity concentration of the second doped region 74 is higher than that of the first doped region 64, and lower than that of the third doped region 82. The graded structure of the source region 84 may be formed, for example, by means of a special annealing process to diffuse impurities or by means of an annealing process performed during the fabrication of an EEPROM device. Due to the graded structure, generation of punch-through is suppressed and a high breakdown voltage is generated.

Following the removal of the second ion implantation mask 178, a self-aligned silicide layer, i.e., salicide layer (not shown) may be formed at the source region 84 and the drain region 168 by means of a self-aligned silicidation process. The salicide layer may be formed on the third doped region 82 of the source region 84 to be self-aligned with the outer sidewalls of the spacer patterns 76 on the selection gates 56. The floating region 166 may be covered by the opposing spacer patterns 76 on the selection gate 56 and the memory stack gate 54, so that a silicide layer may be prevented from forming at that location.

In the present embodiment, even when the silicide layer extends to the substrate, increase of leakage current is suppressed at the source region 84, which includes the first doped region 64, the second doped region 74 and the third doped region 82.

According the exemplary embodiments of the present invention, a highly integrated EEPROM device is provided. A source region, in which hopping distances of carriers are long, is formed with a graded structure to have a high breakdown voltage and to suppress generation of punch-through. Because an impurity concentration in the graded structure is higher than in a conventional DDD structure, resistance of a common source line is lowered. In that a relatively deep source region is formed while suppressing generation of punch-through, a source structure of low leakage current is achieved when a salicide structure is adopted to lower resistance.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. An electrically erasable programmable read-only memory (EEPROM) device, comprising:
a semiconductor substrate;
an EEPROM cell located on the semiconductor substrate, the EEPROM cell comprising a memory transistor and a selection transistor;
a source region and a drain region located on the semiconductor substrate adjacent to opposite sides of the EEPROM cell, respectively, the source region comprising a first doped region, a second doped region and a third doped region; and
a floating region positioned between the memory transistor and the selection transistor,
wherein the first doped region surrounds a bottom surface and sidewalls of the second doped region, and the second doped region surrounds a bottom surface and sidewalls of the third doped region.

2. The EEPROM device of claim 1, wherein a second impurity concentration of the second doped region is higher than a first impurity concentration of the first doped region and lower than a third impurity concentration of the third doped region.

3. The EEPROM device of claim 1, wherein impurity ions in the first doped region and third doped region comprise phosphorus (P) and arsenic (As), and impurity ions in the second doped region comprise As.

4. The EEPROM device of claim 1, further comprising:
a self-aligned silicide layer on the third doped region.

5. The EEPROM device of claim 1, wherein each of the floating region and the drain region comprises the same impurity concentration and depth as the first doped region.

6. The EEPROM device of claim 1, wherein each of the floating region and the drain region comprises the same impurity concentration and depth as the second doped region.

7. An electrically erasable programmable read-only memory (EEPROM) device, comprising:
an active region defined on a semiconductor substrate;
a first drain region and a second drain region separated from each other in the active region;
a first sensing line and a second sensing line positioned between the first drain region and the second drain region, and crossing over the active region adjacent to each of the first drain region and the second drain region;
a first wordline and a second wordline positioned between the first sensing line and the second sensing line;
spacer patterns positioned on sidewalls of the first and second sensing lines and the first and second wordlines;
a first floating region positioned on the active region between the first wordline and the first sensing line, and a second floating region positioned on the active region between the second wordline and the second sensing line; and
a common source region positioned on the active region between the first wordline and the second wordline, the common source region comprising a first doped region, a second doped region and a third doped region,
wherein the first doped region surrounds a bottom surface and sidewalls of the second doped region, and the second doped region surrounds a bottom surface and sidewalls of the third doped region.

8. The EEPROM device of claim 7, wherein a portion of the active region between the first and second wordlines is exposed between adjacent spacer patterns, and
wherein a portion of the active region between the first wordline and the first sensing line and a portion of the active region between the second wordline and the second sensing line are covered by adjacent spacer patterns.

9. The EEPROM device of claim 8, further comprising:
a silicide layer positioned on the exposed portion of the active region between the first and second wordlines and aligned with an outer sidewall of the each of the adjacent spacer patterns.

10. The EEPROM device of claim 8, wherein each of the first wordline and the second wordline is partially superposed on the first doped region and each of the adjacent spacer patterns is superposed on the second doped region; and
wherein the third doped region is located within the exposed portion of the active region between the first and second wordlines.

11. The EEPROM device of claim 10, wherein each of the first and second floating regions and the first and second drain regions comprises the same impurity concentration and depth as the first doped region.

12. The EEPROM device of claim 10, wherein each of the first and second floating regions and the first and second drain regions comprises the same impurity concentration and depth as the second doped region.

13. The EEPROM device of claim 7, wherein impurity ions implanted into the first doped region and the third doped region comprise phosphorus (P) and arsenic (As), and impurity ions implanted into the second doped region comprise As.

14. The EEPROM device of claim 13, wherein impurity ions implanted into each of the first and second floating regions and the first and second drain regions comprise phosphorus (P) and arsenic (As).

15. The EEPROM device of claim 13, wherein impurity ions implanted into each of the first and second floating regions and the first and second drain regions comprise arsenic (As).

16. A method of fabricating an electrically erasable programmable read-only memory (EEPROM) device, comprising:
forming a memory gate stack and a selection gate on a semiconductor substrate;
implanting impurities into the semiconductor substrate to form a floating region between opposing sidewalls of the memory gate stack and the selection gate, to form a first doped region adjacent to an opposite sidewall of the selection gate, to form a second doped region having a bottom surface and sidewalls surrounded by the first doped region, and to form a drain region adjacent to an opposite sidewall of the memory stack gate;
forming spacer patterns on the sidewalls of the selection gate and the memory gate stack; and
implanting impurities into the semiconductor substrate to form a third doped region adjacent to the spacer pattern formed on the opposite sidewall of the selection gate, the third doped region having a bottom surface and sidewalls surrounded by the second doped region.

17. The method of claim 16, wherein the floating region, the first doped region and the drain region are formed simultaneously.

18. The method of claim 16, wherein the floating region, the second doped region and the drain region are formed simultaneously.

19. The method of claim 16, wherein a second impurity concentration of the second doped region is higher than a first impurity concentration of the first doped region and lower than a third impurity concentration of the third doped region.

20. The method of claim 16, further comprising:
applying a self-aligned silicide layer to the semiconductor substrate on the third doped region.
